(19) United States
(12) Patent Application Publication
(10) Pub. No.: US 2007/0240093 A1
(43) Pub. Date: Oct. 11, 2007

(54) Architecture and method for providing integrated circuits

(75) Inventor: Paul Short, Albuquerque, NM (US)

Correspondence Address: DONALD J LENKSZUS, PO BOX 3064, CAREFREE, AZ, 85377-3064, US

(73) Assignee: Quadric, Inc., Albuquerque, NM (US)

(21) Appl. No.: 11/787,206

(22) Filed: Apr. 10, 2007

Related U.S. Application Data
(60) Provisional application No. 60/790,637, filed on Apr. 10, 2006.

(51) Int. Cl. G06F 17/50; H03K 19/00

(52) U.S. Cl. 716/17

(57) ABSTRACT

A customizable integrated circuit is programmed to provide both hardware task functions and interconnects. A plurality of execution units is executable concurrently to emulate hardware tasks. A plurality of programmable locations provides logical interconnect between the executable programs.

### RELATED APPLICATIONS

This application claims the benefit of and priority based upon U.S. provisional application for patent 60/790,637 filed on Apr. 10, 2006.

### FIELD OF THE INVENTION

The invention pertains to integrated circuit design, in general, and to a system and method of providing customized integrated circuits, in particular.

### BACKGROUND OF THE INVENTION

There is a demand for customized Integrated Circuits (“ICs”). Customization allows companies to differentiate themselves from the competition by placing specialized, user-specific functions on the IC. Though custom lCs have existed since the dawn of the semiconductor industry, the effects of Moore's law have increased the complexity of ICs to such an extent that the nature of the design has changed. Those changes will continue in the future, creating a need to improve design productivity dramatically.

Designing a custom chip is an exercise in defining two items: (a) logic, which takes input signals, performs an algorithm on them, and sets outputs based on that algorithm; and (b) interconnect which ties the blocks of logic together, describing where each input of a logic block comes from and where each output of a logic block goes to.

Current custom IC implementations comprise a set of logic blocks 101, 102, 103, 104, 105, 106 implemented in hardware, operating concurrently, as shown in FIG. 1. A logic block 101, 102, 103, 104, 105, 106 can be any logic function such as, for example, an Ethernet port, a CODEC, random logic, or even a processor. Each logic block 101, 102, 103, 104, 105, 106 must be designed independently and the logic blocks are coupled together with interconnect 107.

Two major technologies currently used to implement custom ICs currently are Application Specific Integrated Circuit (ASIC) and Field Programmable Gate Array (FPGA). With ASIC technology, an ASIC supplier provides a designer with a library of pre-configured logic cells with which the customer defines the logic. The customer also defines the interconnect. ASIC suppliers build wafers of ICs with the customer's defined logic and interconnect. ASICs, once built, are fixed. The logic and interconnects cannot change.

FPGA suppliers, on the other hand, build wafers of chips that contain blank, programmable logic blocks with similarly programmable interconnects. The customer loads a configuration into the chip that defines all the logic blocks and interconnects.

There are variations of each technology. For instance, ASICs can be standard-cell, gate array, or Platform ASIC, and FPGAs can be based on SRAM or FLASH. Some suppliers in the market combine the technologies. Thus, there are chips sold in which sections are hard-wired using ASIC technology, and other sections programmable using FPGA technology. Platform ASIC and Platform FPGAs add pre-configured pieces (usually processors) to the general platform. One supplier uses programmable logic and fixed interconnect. Still, all main solutions are based on the two primary technologies, and each technology has its pros and cons. The pros and cons consist of tradeoffs between development time and cost, recurring parts costs, and performance.

ASIC technology has high performance and low recurring cost, but can cost tens of millions of dollars to design at 180 nm and below. Mask costs add another million dollars or more. The technology is hard-wired, meaning that it cannot be changed once it is manufactured. Thus it requires a project with very high volumes to justify a full-fledged ASIC development. The schedules are long, especially when re-spins are necessary, and the risks are enormous.

The cost to develop an FPGA is much less than ASIC, but the chips are much larger than an equivalent ASIC, so recurring costs are far higher, e.g., $2500 per device at the high end. Further, performance is much lower and power consumption is higher than ASIC. System designers must, then choose the right technology based on requirements, but there is always a tradeoff between development and recurring costs and levels of performance.

The design costs, and thus risks, associated with ASICs and FPGAs are driven by the staffing necessary to implement the hardware design. FPGAs mitigate the risk by allowing changes in the field, but tradeoff this advantage with decreased performance and increased parts costs. FPGAs are designed more like software—the function is coded, placed in the part, and run. It can be changed much more easily than ASIC functionality, much like software.

Significant effort has been expended to make the design of hardware more like software, garnering the increased productivity and lower development costs of the software model. The advent of hardware design languages, such as Verilog, was followed by FPGAs as part of an overall trend toward soft design of hardware.

### SUMMARY OF THE INVENTION

The present invention completes the transformation to soft design, and thus represents a third technological solution to implement custom Integrated Circuits. In accordance with the principles of the invention a single chip processor, specially architected in accordance with the principles of the invention, is provided that is customizable to provide customer specified logic functions and interconnects. The architecture runs software code in parallel, and further in accordance with the principles of the invention, performs all the customized logic and interconnect functions. The specially-architected processor is even easier to customize, but still outperforms and uses less power, than an FPGA while remaining much less expensive to produce. Compared to an ASIC, it is orders of magnitude less costly to customize, while approaching the performance level of an ASIC.

In accordance with the principles of the invention, a customizable integrated circuit includes a meta-processor configuration operable to concurrently execute a plurality of tasks. A plurality of executable programs for operating the meta-processor in accordance with corresponding algorithms is programmed into the meta-processor. The meta-processor operates to execute the plurality of executable programs in parallel. In the illustrative embodiment of the invention, a plurality of programmable memory mailboxes provides logical interconnect between the executable programs.

### BRIEF DESCRIPTION OF THE DRAWING

The invention will be better understood from a reading of the following detailed description, in conjunction with the several drawing figures in which like reference designators are utilized to identify like parts, and in which:

FIG. 1 is a block diagram of a representative prior art IC implementation;

FIG. 2 is a functional block diagram of one architecture in accordance with the principles of the invention;

FIG. 3A illustrates the task execution of a typical prior art arrangement;

FIG. 3B illustrates the task execution of the architecture of FIG. 2;

FIG. 4 illustrates a processor instruction word for the architecture of FIG. 2;

FIG. 5 is a block diagram of the I/O execution unit of FIG. 2;

FIG. 6 illustrates the mapping of logic blocks;

FIG. 7 illustrates task control/compacting utilized in the architecture of FIG. 2;

FIGS. 8 and 9 illustrates task compacting utilized in the architecture of FIG. 2;

FIG. 10 illustrates the compacting priority;

FIGS. 11 and 12 illustrates task communication;

FIG. 13 is a block diagram of a system-on-chip IC processor;

FIG. 14 is a functional block diagram of a system-on-chip embodiment in accordance with the principles of the invention;

FIG. 15 illustrates a meta-processor instruction word for the architecture of

FIG. 16 illustrates task compacting utilized in the architecture of FIG. 14;

FIG. 17 illustrates the compacting utilized in the architecture of FIG. 14;

FIG. 18 illustrates the compacting priority of the architecture of FIG. 14; and

FIG. 19 illustrates task communication for the architecture of FIG. 14.

### DETAILED DESCRIPTION

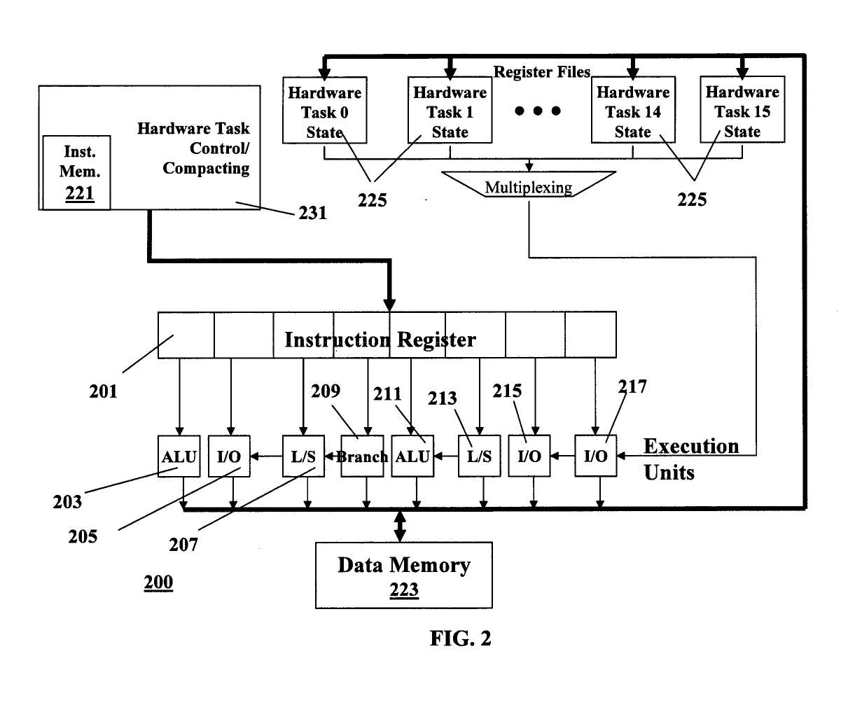

A first embodiment architecture in accordance with the principles of the invention is shown in FIG. 2. The architecture of FIG. 2 is a meta-processor 200 that allows concurrent execution of many tasks. It is based on a Very Long Instruction Word (VLIW) architecture, which has natural concurrency as part of the architecture. Users of the present invention design the hardware functions with software tools, dramatically reducing development costs.

The architecture of the present invention is a VLIW meta-processor that is a super ‘bit-bang’ machine, i.e., a processor that toggles the I/O of a chip using software, rather than hardware. Logic is implemented in software, running the algorithms that today's ASICs and FPGAs perform in hardware. Interconnect is implemented through memory mailboxes between programs. Both are described in more detail below.

VLIW processors differ from typical processors, e.g. the x86 series, in the length of the instruction word. Typical processors have 16 or 32-bit instruction words. Some advanced processors use as much as 64 bits. The instruction is coded to control the various execution units such as ALU, Load/Store, Branch, or Floating Point units. Without additional specialized hardware, a typical processor executes one instruction at a time, and thus only one execution unit will be active at a time.

VLIW architecture widens the instruction word to handle control of all execution units simultaneously. A VLIW instruction can be 128, 256, or even 512 bits wide, depending on the amount and kind of execution units needed. It can therefore execute many instructions at once. A 256-bit VLIW engine can, for example, execute sixteen 16-bit instructions or eight 32-bit instructions concurrently. It can even be a mixture of widths, though that is rarely done.

This architecture allows VLIW processors to be simpler because they do not need special hardware to re-order instructions to improve performance.

A problem with current VLIW implementations is that compilers cannot efficiently fill all instruction words in the instruction register. Thus many of the execution units are idle, eliminating much of the advantage of otherwise using a VLIW architecture.

In contrast with prior VLIW implementations, the architecture of the present invention emulates hardware units, and hardware units are naturally concurrent.

The present invention overcomes the limitation through the use of Hardware Tasks—software routines running on the VLIW meta-processor that are coded to act like a logic block. A Hardware Task might be coded to perform the functions of an Ethernet MAC, a UART, a Multiplier, a CODEC, or even a typical processor. No separate peripherals are needed.

Because each Hardware Task is a separate, independent piece of code that emulates a logic block, multiples of them efficiently run on a VLIW processor. They are compacted in the Task Control/Compacting unit, as described below, so that the VLIW instruction word is used to its fullest extent possible. Each Hardware Task can be thought of as a separate processor, though it shares some resources with the other hardware tasks.

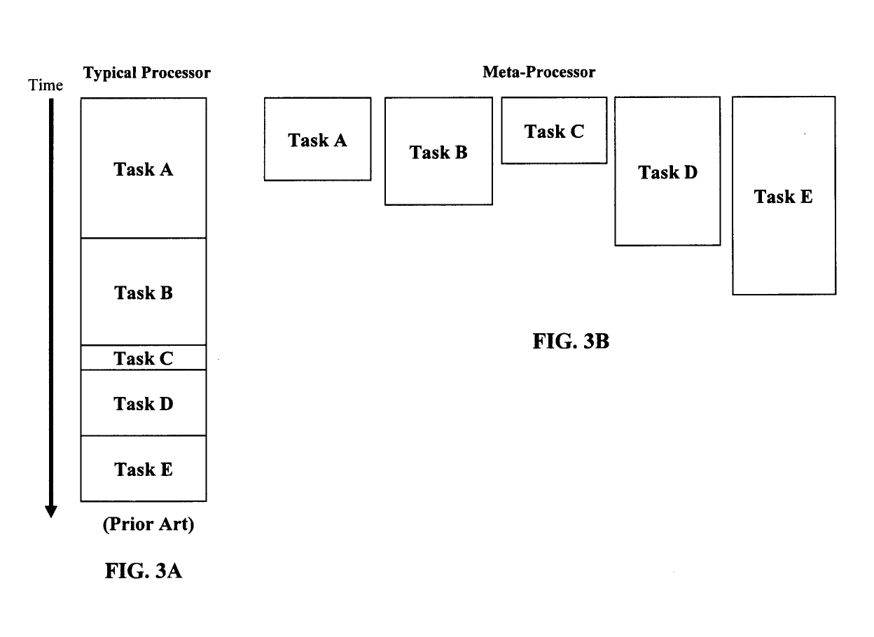

FIGS. 3A and 3B illustrate how the architecture of the present invention executes programs compared to a typical processor. A typical processor runs tasks sequentially—one at a time as shown in FIG. 3A. It executes code for one task, e.g. Task A, switches to code for the next task, e.g. Task B, and executes the code for the next task. Switching between tasks (or contexts as they are sometimes called) is time-consuming, as the processor needs to gather the right data in the registers and switch over to a new set.

The architecture of the present invention runs all the programs all the time as shown in FIG. 3B, in every clock cycle. Every Hardware Task, i.e., Task A, Task B, Task C, Task D, Task E, has the opportunity to execute some or all of the instructions in its instruction register or instruction register portion. The architecture of the invention provides for resource sharing as described below, and as a result, an individual task may take longer to run on meta-processor. Task D and Task E, shown here as lower-priority tasks, are examples of this. However, because all the tasks Task A, Task B, Task C, Task D, Task E are running all the time, the overall amount of time taken to execute all tasks will be significantly shorter.

Specific implementation depends on the target application. Two architecture implementations are described herein: a simple Logic-only implementation and a more complex System-on-Chip implementation. It will be appreciated by those skilled in the art that it is not intended that the invention is limited to the embodiments shown and that changes and modifications may be made to the shown implementations without departing from the scope of the invention. The implementations shown and described are examples of how the architecture in accordance with the principles of the invention can be used.

A logic-only embodiment of an architecture in accordance with the invention executes simpler logic functions, much as FPGAs do now. A typical processor's software functions are not emulated in this implementation. Only logic, such as interface functions, translation of data formats, and special-purpose random logic, is emulated. It should be noted, however, that the functionality is limited only by the size of the instruction memories and the overall processing bandwidth of the device. Any function that can be written in software can run on this implementation. In the Logic-Only implementation, there are 16 Hardware Tasks.

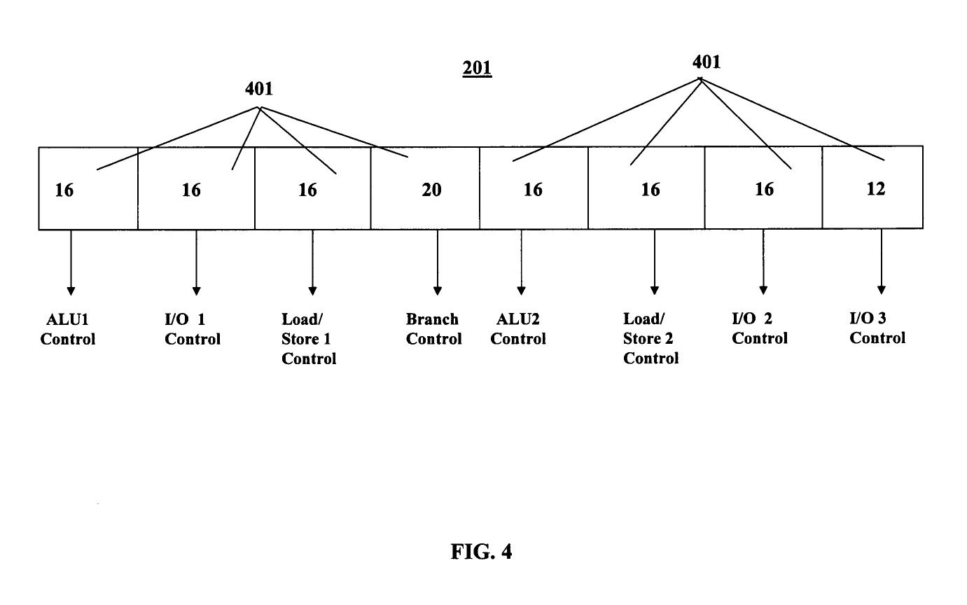

The logic only embodiment has a 128-bit wide instruction register 201, shown in greater detail in FIG. 4. Instruction register 201 is broken into Instruction Words 401. Each Instruction Word 401 contains the proper number of bits of data to control an Execution Unit 203, 205, 207, 209, 211, 213, 215, 217. In this case, each Execution Unit 203, 205, 207, 211, 213, 215 has 16 bits of control, with the exception of the Branch control unit 209, which has 20 bits, and the I/O control 217, which has 12 bits. Thus, this implementation is equivalent to a collection of 16-bit processors. Branch control unit 209 has 20 bits to allow for a more robust program size.

The architecture of the meta processor 200 does not limit the instruction register 201 to the set of features shown. The instruction register 201 may be 128-bits in one implementation, 256 in another, and 512 in a third. The individual instruction words for the execution units are not required to be 32-bits. They can be 4, 8, 16, 32, or 64 bits for instance, or any number of bits. The execution unit instruction word lengths can be of mixed length in any one implementation. That is, a 256-bit instruction may have four 32-bit instruction words, six-16 bit instruction words, seven 8-bit instruction words, and two 4-bit instruction words. In any case these are referred to as “instruction words”, a term that stands for a set of bits used to control one execution unit.

There are 8 execution units 203, 205, 207, 209, 211, 213, 215, 217 in meta processor 200. A functional description of each unit is provided below. It will be understood by those skilled in the art that the invention is not limited to the specific execution unit functions described. Other execution unit functions may be provided.

Arithmetic logic execution units 203, 211 (ALU1 & ALU2) are each capable of adding, subtracting, shifting, AND, OR, XOR, NOR, and similar bit manipulations of data.

Branch control execution unit 209 calculates the location in instruction memory 221 of a branch or jump instruction.

Load/Store control execution unit 207 reads and writes to data memory 223 and to register files 225.

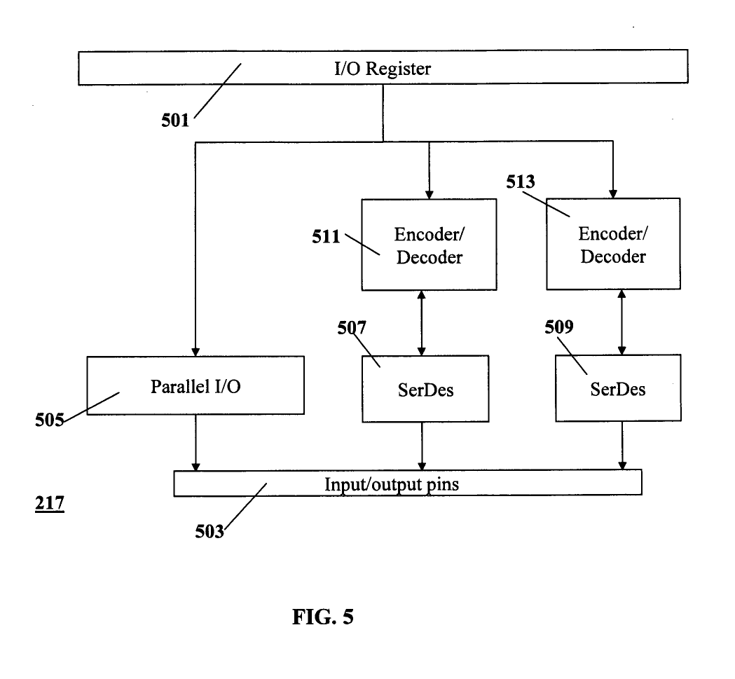

A representative one of the I/O execution units 205, 215, 217 is shown in FIG. 5. Each I/O execution unit 205, 215, 217 receives data from an instruction via I/O register 501 and places the data onto I/O pins 503. Data may be placed onto I/O pins 503 be direct via parallel I/O 505 or it can be channeled through the serializer/deserializer units 507, 509. Inputs from I/O register 501 are encoded in either 4B/5B, 8B/10B, Manchester, NRZ, or NRZI by one of encoder/decoders 511, 513 and then placed on an output pin 503 in a serial fashion. Similarly, execution units 205, 215, 217 take a serial input from an input pin, decodes it from any of the above encoding schemes utilizing encoder/decoders 511, 513, and places a 16-bit word in I/O register 501 for the Instruction to use.

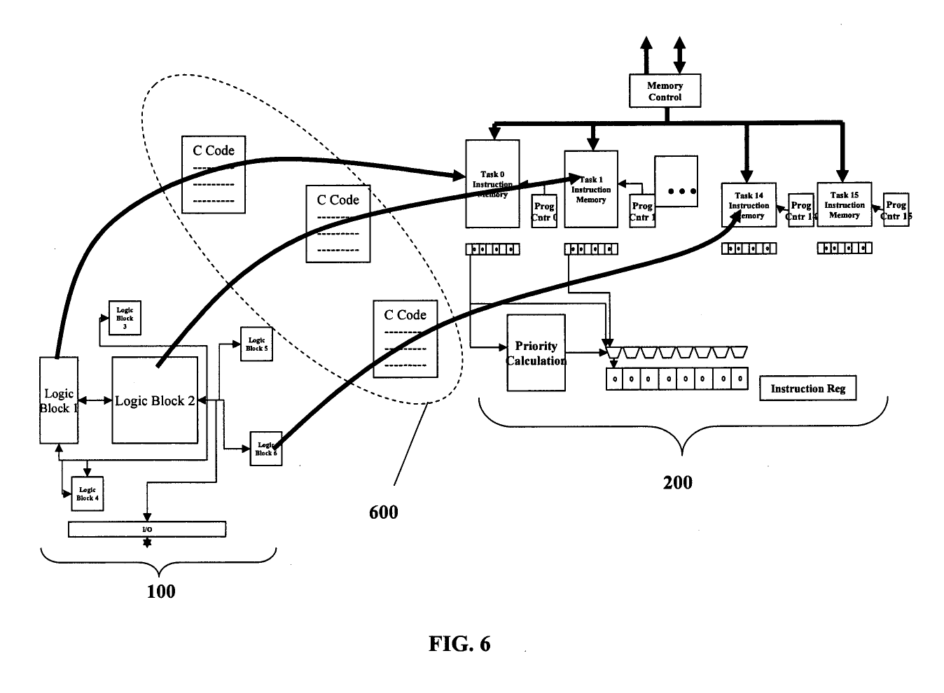

In accordance with the principles of the invention, meta processor 200 utilizes what would in the past be considered to be hardware tasks as software programs that emulate logic blocks in a typical custom IC. FIG. 6 illustrates hardware task to software mapping. Hardware tasks 100 are written like any software program. In the illustrative embodiment the users write hardware tasks 100 in the C language, though they could write in assembly language or in hardware or system description languages such as Verilog or System C. A full set of tools 600, including Compilers, Linkers and Debuggers is provided and other commercially available design tools such as Electronic System Level tools and synthesis tools are supported. The tools 600 output a binary file that contains all the code parsed into instruction words.

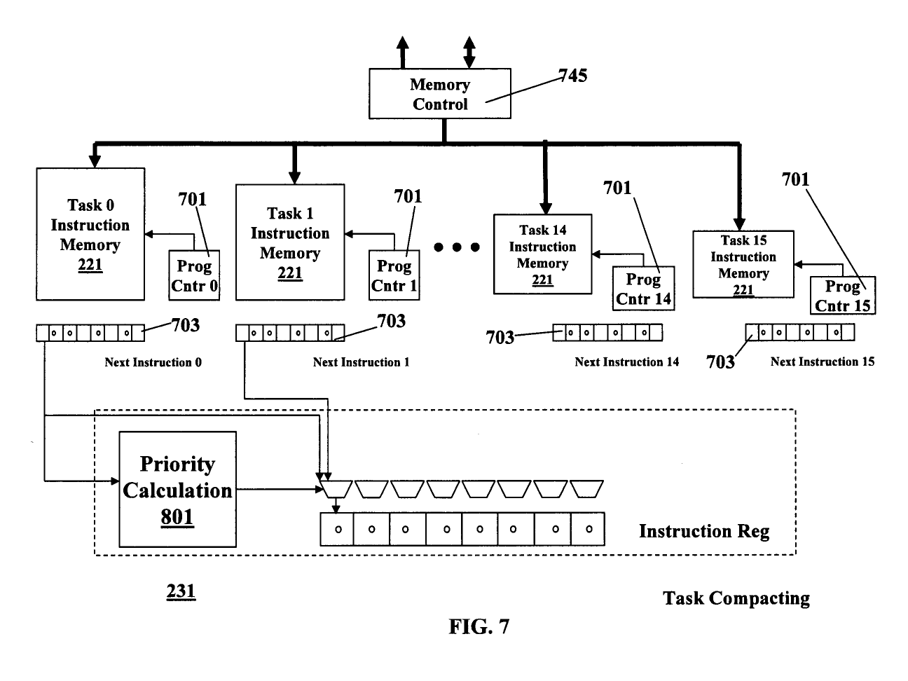

As shown in FIGS. 6 and 7 each hardware task 100 has an instruction memory 221 associated with it where the code for that task resides. The size of each memory 221 is allocated based on the size of the corresponding task. Hardware task 0 as shown here has a larger instruction memory 221 associated with it than task 15, allowing for more complex tasks to be run in task 0 and simpler tasks in task 15, while conserving die space. The specific sizes of the instruction memories 221 are set based upon market requirements during the part definition phase.

In this embodiment of the invention, the entire hardware task program must fit into the task instruction memories 221, however, in other embodiments of the invention that may not be the case.

After a hardware task binary has been stored in an instruction memory 221, it can then be executed. Hardware tasks are executed through a combination of resources. General purpose registers, some special purpose registers, instruction memory 221, program counters 701, and a next instruction registers 703 are resources dedicated to a single hardware task. Data memory 223, some special purpose registers, task compacting 231, and execution units 203, 205, 207, 209, 211, 213, 215 are shared resources between the hardware tasks.

A program counter 701 as shown in FIG. 7 controls from where in its associated instruction memory 221 the next instruction will be fetched. That instruction is called the “next instruction”, and is loaded into the next instruction register 703 allocated to that hardware task. Each program counter 701, in conjunction with the branch execution unit 209, is capable of simple incrementing for standard next-instruction execution, and is capable of being loaded from the branch execution unit 209 to support jumps, branches, etc.

Each hardware task has its own register file 225, as shown in FIG. 2, for storing data and control. In the Logic-Only embodiment of the meta processor 200, each task has thirty-two 16-bit general-purpose registers. Hardware tasks do not share general-purpose registers, nor can one task write to or read from another task's general purpose registers.

Some special-purpose registers are provided. Each hardware task has a set of task communication registers, a program counter, and others as necessary.

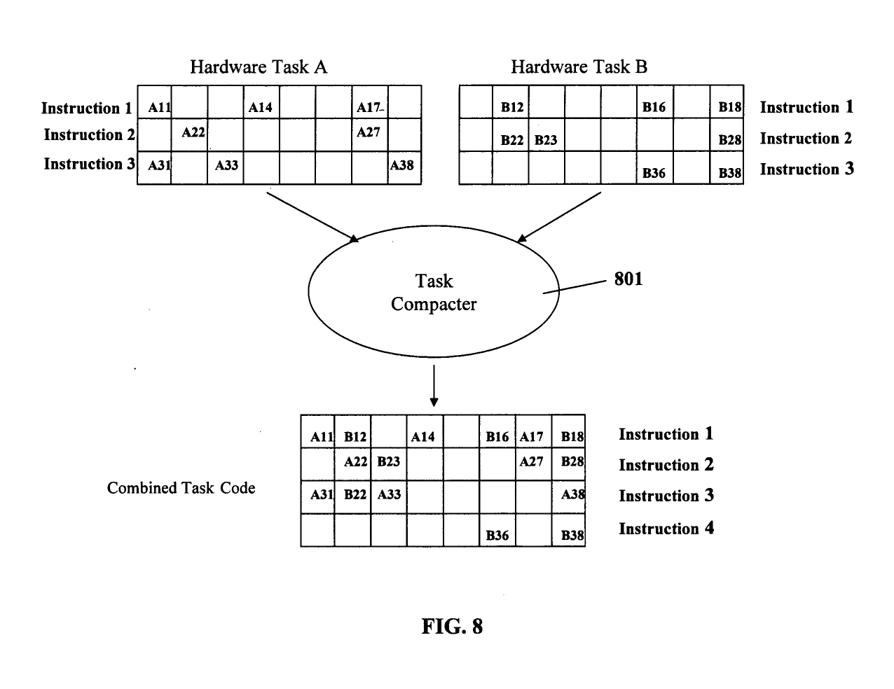

Task compacting takes advantage of the natural concurrency of the hardware tasks, i.e. hardware tasks are not dependent on each other for execution. Thus the instructions can be combined efficiently. FIG. 8 shows a simple example. Two Hardware Tasks, A and B, are to be compacted. Task A is the higher priority. In the first instruction, only three 16-bit Instruction words are used by Task A, however. The same is true for Task B. The task compacter 801 places the highest priority instruction into the Instruction Word first, followed by the next highest priority. For Instruction 1, this works well—all six Instruction Words from both Hardware Tasks fit into the Instruction Word.

For instruction 2, however, both Hardware Tasks use the second Instruction Word. The task compacter 801 places Task A's full instruction into the Instruction Word and then all the non-conflicting words from Task B. Thus B23 and B28 are placed in the Instruction Word, but B22 is not, because it conflicts with A22. During the next instruction cycle, the process repeats, except Task B must finish the previous instruction (Task B, instruction 2) before it can begin to execute its next instruction (Task B, instruction 3). Thus the next instruction will be filled with Task A's third instruction, and the remaining instruction words from Task B. In this case, that is a single instruction word (B22), and it happens that Task A does not fill that Instruction Word, so Instruction 3 has all of Task A's 3rd instruction and the remaining Instruction Words from Task B. Because there are only 3 instruction in this simple example, the last instruction is simply task B's final instruction. So 6 instructions (3 each from Tasks A and B) are executed in 4 instruction cycles, with plenty of space left for additional tasks.

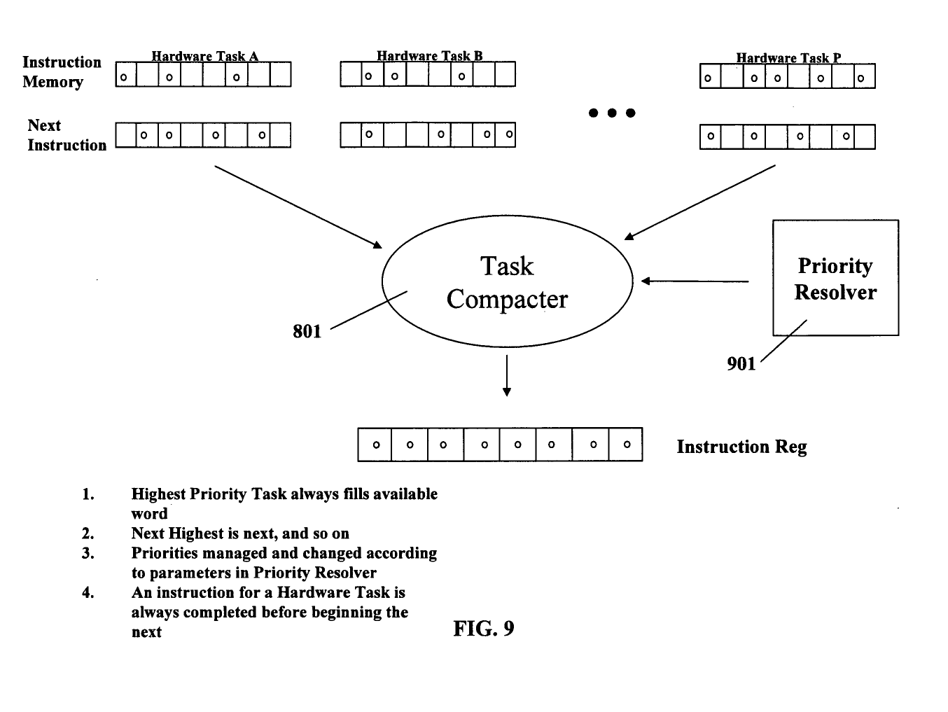

Compacting is expanded to include all Next Instructions for all 16 Hardware Tasks. As seen in FIG. 9, starting with the Next Instructions, the compacting unit begins with the highest priority task (Task A), and places all of its Instruction Words into the Instruction Register. The next highest priority task will fill any Instruction Words that it uses, but that Task A did not fill. This continues until Hardware Task P, the lowest priority Hardware Task, has its chance at having some or all of its Instruction Words loaded into the Instruction Register.

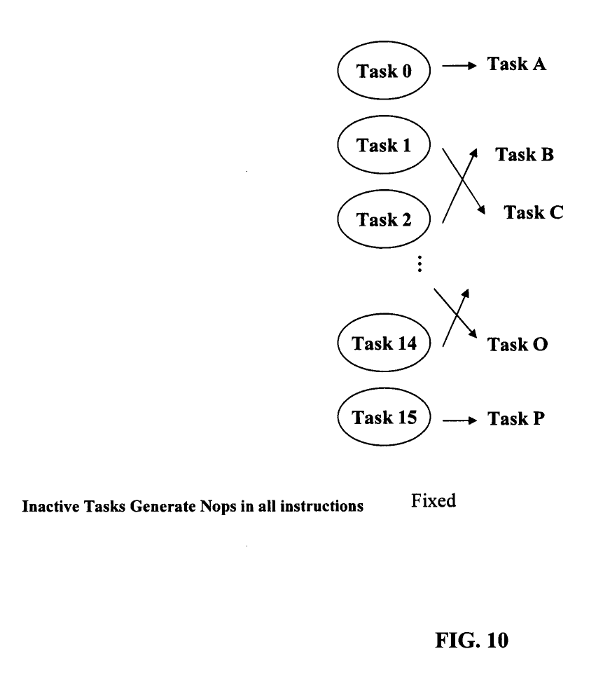

Hardware Tasks are compacted according to a priority that is set by the user. In the logic only embodiment, priority is a simple, fixed allocation: one Hardware task to one priority, as shown in FIG. 10. Priority is set on a highest to lowest basis. Any task can be allocated to any priority, with the caveat in this embodiment that there is only one hardware task per priority level. No two hardware tasks can occupy the same priority.

There may be instances where the hardware task is waiting for an external event, and so has nothing loaded into its Next Instruction. In that case, it is simply passed over and the next highest priority task takes its place. Also, a task may be inactivated, meaning it is either temporarily or permanently not needed. If a task is inactive, it is taken out of the compacting priority list.

Thus it is clear that all tasks are being executed all the time. They have different priorities for fitting into the instruction word, and so may execute at different throughput rates, but they all execute every clock cycle. Going back to FIG. 3, we see how sharing the execution units 203, 205, 207, 209, 211, 213, 215, 217 affects the amount of time a task will take to finish. In this example, since Task A is the highest priority task, it will execute faster than a typical processor because it has numerous execution units available to it. Similarly with Task B, however it will be more equivalent. Task E, the lowest priority task, will take longer because it will not have the plethora of resources available to it that Task A does. However, because all the tasks are executing all the time, the overall time taken to execute all the tasks is substantially reduced.

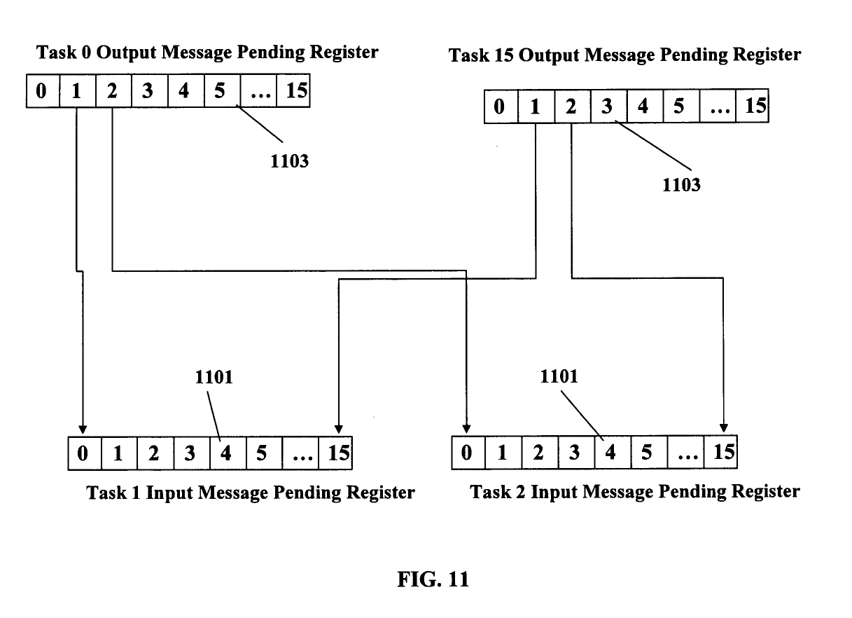

Hardware tasks communicate with each other through a mailbox system. Each hardware task has access to an input message pending register 1101. This is a 16-bit register in which each bit, when it is activated, indicates that a message is pending from another hardware task, as shown in FIG. 11. In each input message pending register 1101, bit 0 indicates that Task 0 has a message pending to that task. Task 0 is the only task that can write to Bit 0 of any input message pending register 1101.

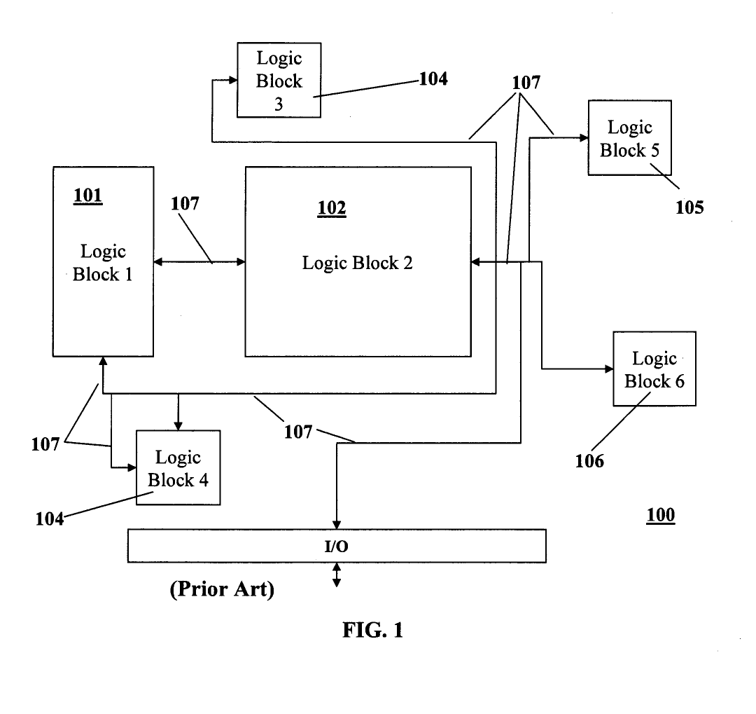

Each Hardware Task can write to 16 bits, via an output message pending register 1103, with each bit communicating to the corresponding hardware task that a message is pending for it. As seen in FIG. 1, Task 0 can write to its output message pending register 1103 bit 1. If that bit is set to active, then Task 1's input message pending register 1101 bit 0 is activated, and Task 1 knows that it has a message pending from Task 0. Similarly, if Task 15 activates bit 2 in its output message pending register 1103, then bit 15 of Task 2's input message pending register 1101 is activated, and Task 2 knows that it has a message pending from Task 15.

Each hardware task can read its output message pending registers 1103 as well as write to it. When a hardware task is finished reading a message, it clears the bit from the corresponding input message pending register 1101, letting the sending task know that the message has been handled.

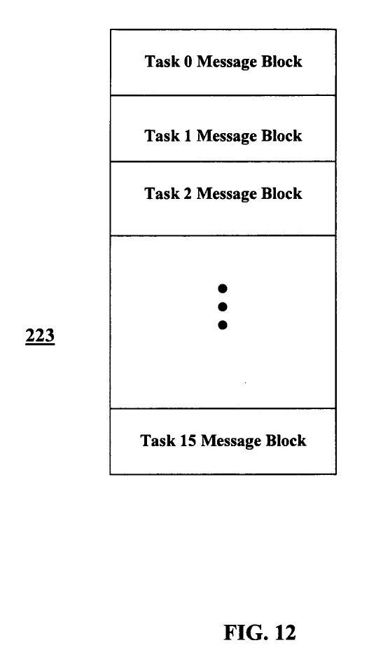

Data for messages is stored in Data Memory in specified locations, as shown in FIG. 12. Task 0 has a specified block in data memory for any message to any other hardware task. In this implementation, the block is of fixed length at a fixed location, though that may not be so for other implementations. Thus any task knows the precise location of any message from any other task.

In accordance with the principles of the invention software techniques are applied to the execution of hardware tasks.

Control of the hardware execution is via a processor-like sequencer. Because a hardware task is now running on a sequential engine, it becomes possible to provide for the conditional execution of hardware tasks. This may be useful in applications that require different algorithms to be run at different times. Rather than having to place all possible hardware implementations in an array (such as an FPGA or ASIC), the present invention allows the unused hardware to remain dormant within the program memory and only be executed when needed.

Hardware data path (or algorithm) execution is in flexible execution elements that can take instructions rather than being fixed like hardware is.

As in most sequential processor engines, any of the program counters 701 in FIG. 7 can execute branching instructions such as jumps, conditional branches, and subroutine calls. A task that is running can use this feature to make decisions about what hardware tasks or subtasks to run.

As an example, a particular hardware task may be a communication engine that is running half-duplex—that is it either transmits or receives, but does not do both at the same time. In a standard implementation, the FPGA or ASIC must have both transmit and receive hardware in place. In the architecture and method of the present invention, the hardware task can run only transmit when a transmit is needed, and only receive when a receive is needed.

The decision whether to run any hardware task or piece of a hardware task can be made from an external event such as an input pin, from an input from another hardware task, or from a hardware task. That is, input pins, communication from another hardware task, or the logic calculated in a hardware task can be stored in the state registers, which the sequencer can execute a jump or branch to control what piece of the hardware task to execute.

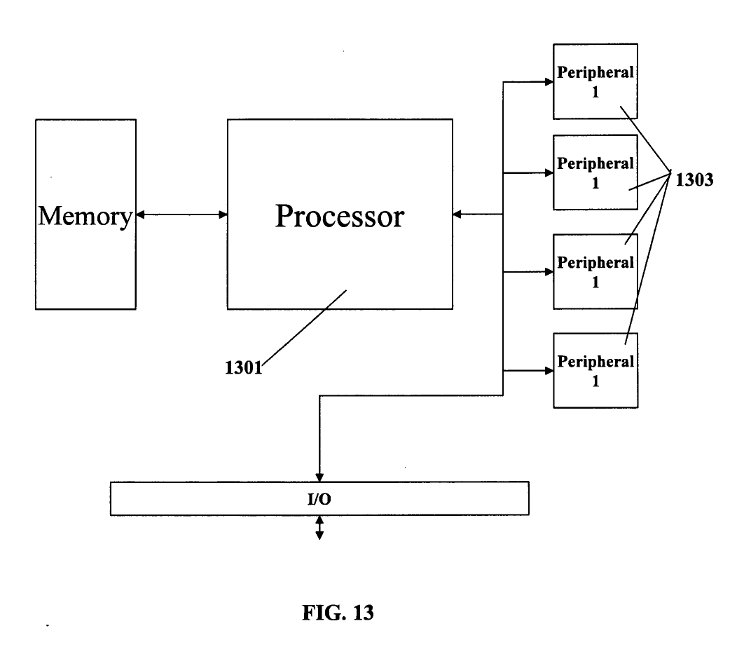

A System-on-Chip (SOC) implementation is a more powerful implementation of the architecture designed to run a System-on-Chip functionality. FIG. 13 shows a typical processor 1301 surrounded by peripherals 1303, which might include multipliers, codecs, I/O engines and the like.

The SOC implementation differs from the Logic-only implementation in a few ways. Only the differences are discussed here.

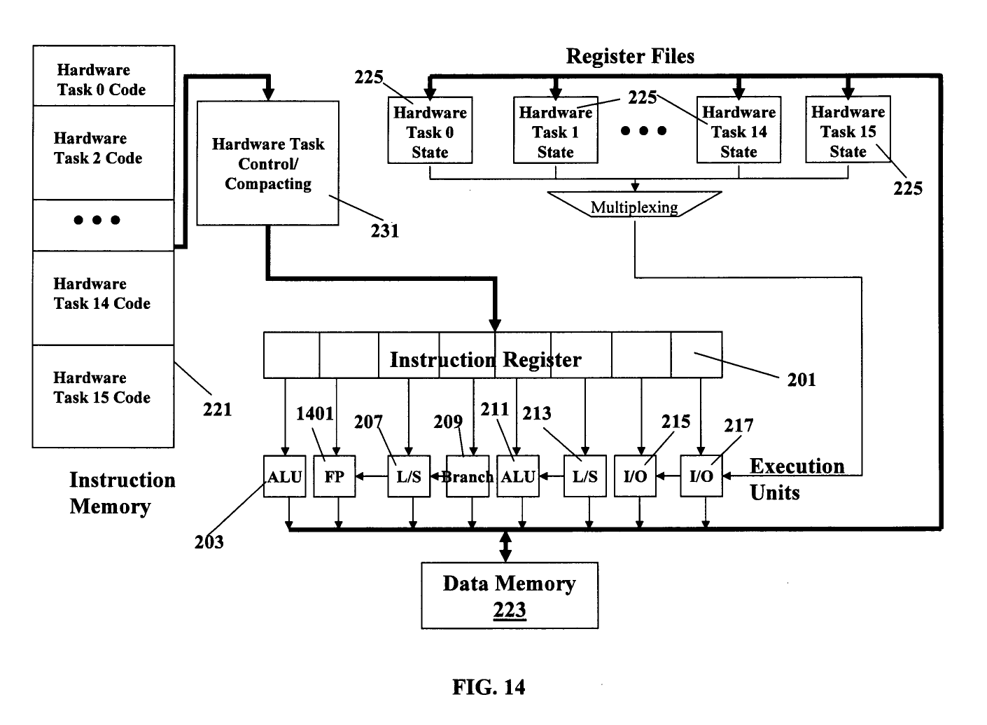

FIG. 14 shows a second embodiment architecture in accordance with the principles of the invention, meant to perform the functions in FIG. 13. A difference in architecture is the addition of instruction memory 221 on-chip, outside of the task control/compacting unit 231. This is because the hardware tasks will be much more complicated, especially when running processor code. Thus the code for each hardware task is located in the instruction memory 221 while the task control/compacting unit 231 contains cache instead of simple instruction memory.

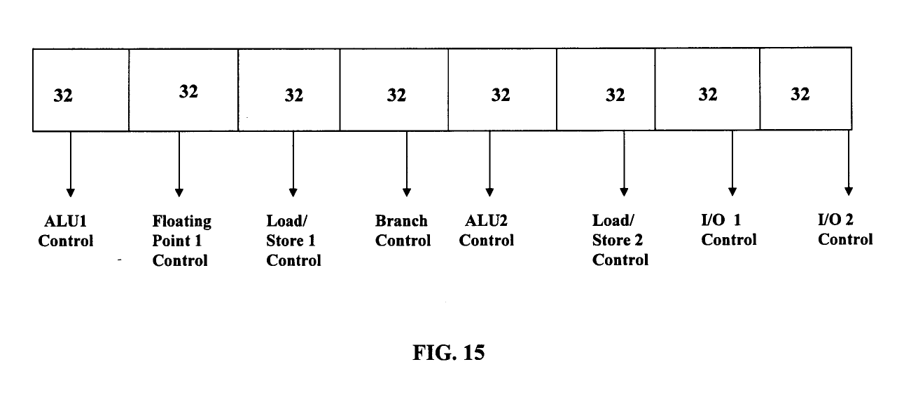

The instruction length is 512 bits, made up of sixteen 32-bit instructions as shown in FIG. 15. It is substantially the same as the logic-only embodiment, with 32-bit-wide instruction words instead of 16.

Execution units 203, 1401, 205, 207, 209, 211, 213, 215, 217 are substantially identical to the logic-only version, except they are all 32-bit wide instead of 16 or 12.

The hardware task code is generated in an identical manner. The tools track what the C-code eventually assembles into.

A change from the logic-only embodiment is the addition of additional hardware tasks. There are 32 hardware tasks rather than 16.

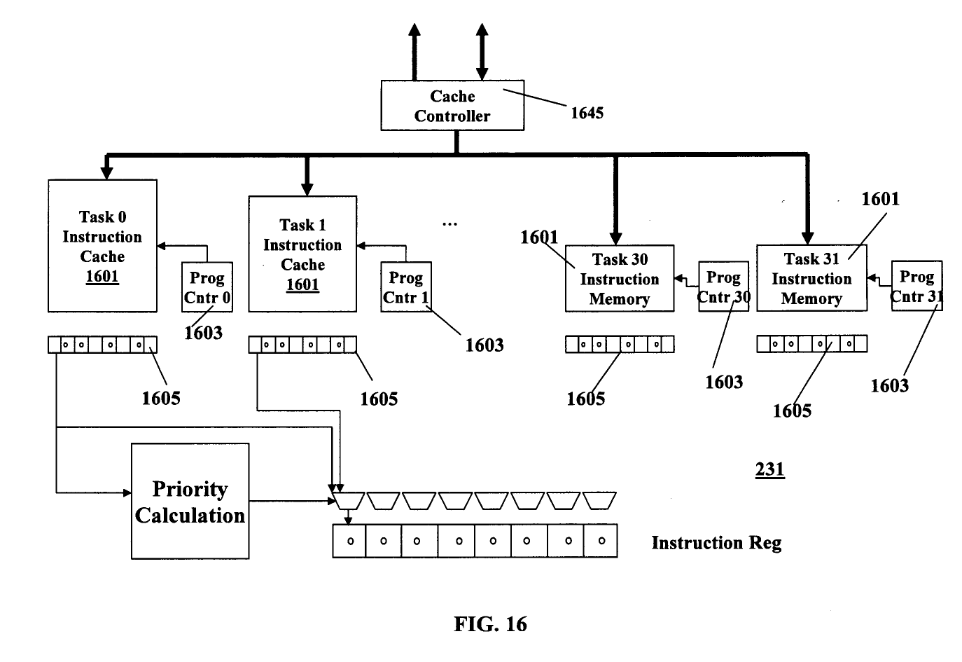

The Task Control/Compacting unit 231 is shown in FIG. 16; Memory Control 745 is replaced with a more complicated cache controller 1645. Once execution begins, the cache controller 1645 begins to take the instructions from instruction memory 221 and place it into one of a plurality of task caches 1601. Task caches 1601 are sized such that Task 0 can hold enough instructions to perform efficient emulation of a processor such as a Coldfire or PowerPC. Task caches 1601 are smaller as the task number is higher, such that the task caches 1601 for tasks 30 and 31 are sized to hold the entire meta-program for a dual UART such as the 16550.

In this cache type implementation cache controller 1645 anticipates the code that will be executed and loads it into an instruction cache 1601. In other embodiments, there may be a mixture of cache and simpler task memory.

Program control of both embodiments is the same, except that in the SOC embodiment, the added feature is that it must work with cache controller 1645, indicating cache misses when the required instructions are not in instruction cache 1601.

There are an identical number of general purpose registers (32), but they are 32-bits wide instead of 16. There are additional task communication special purpose registers as well.

Task compacting for the SOC embodiment is substantially identical with that of the logic-only embodiment, with the difference of instruction length being most significant.

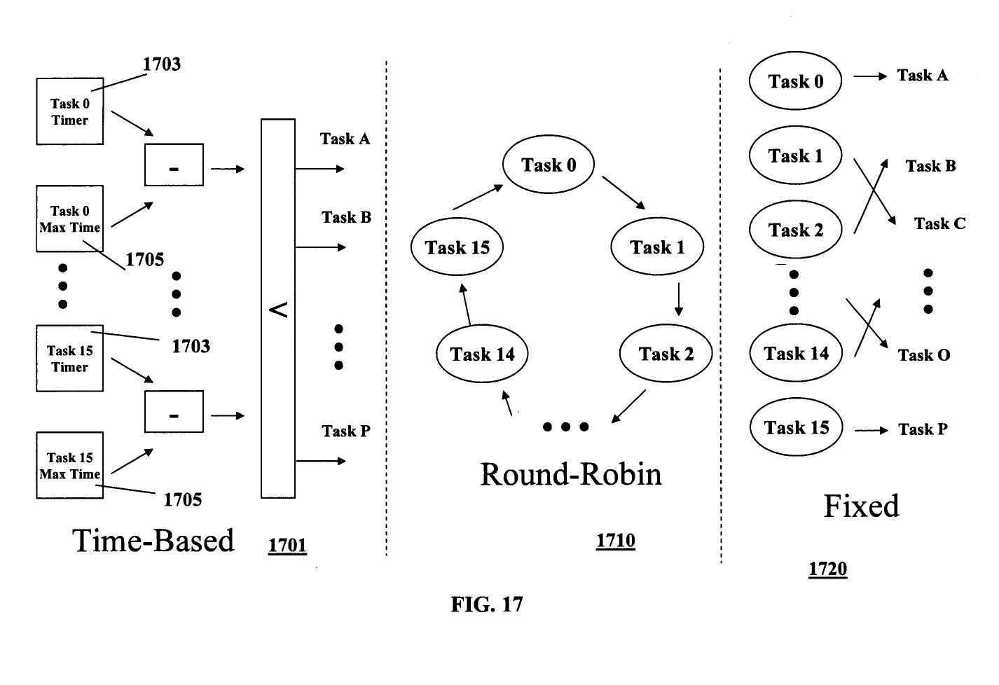

Additional priority schemes may be installed in the SOC embodiment. In addition to fixed priority, the priorities can be changed during execution. Among the different priority schemes available, three priority schemes that may be utilized as shown in FIG. 17. Time-based 1701, round-robin 1710, and fixed 1720 priority schemes are shown. Combinations of the three can be programmed.

Time-based priority 1701 automatically changes the priority based on the time left to execute a hardware task. Each hardware task will have a maximum time programmed into a register, and a task timer 1703. As the timer approaches the maximum time 1705, the priority is increased. Each hardware task, when finished running, will reset its task timer 1703, thus lowering the priority.

Round Robin priority 1710 simply rotates priorities. One cycle, Task 0 might be the highest priority, Task 1 next highest, and so on, culminating in Task 15 being the lowest priority. The next instruction cycle Task 1 will be the highest priority, and Task 0 the lowest. Each instruction cycle the priority changes until, 32 instruction cycles after the first, Task 0 is again the highest priority.

Fixed priority 1720 is identical to the first or logic-only embodiment.

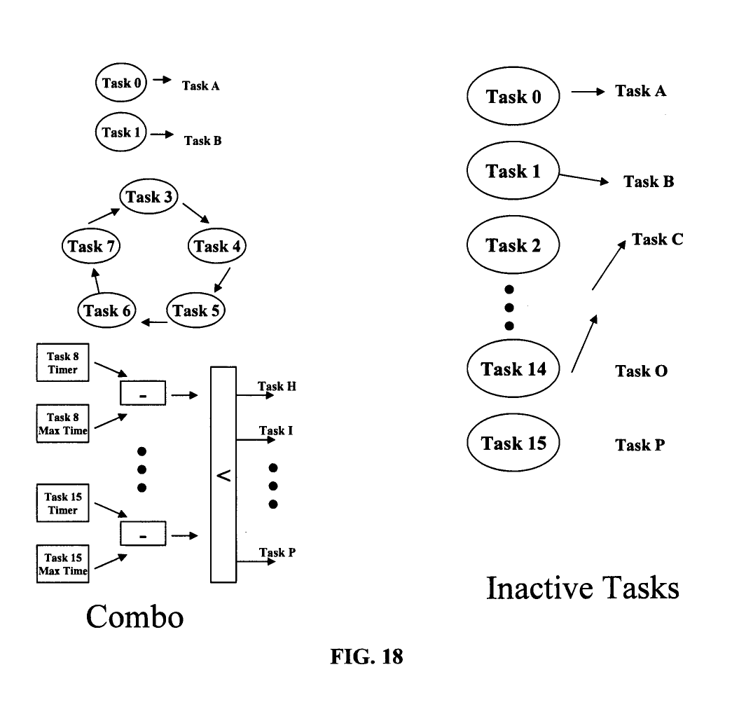

Combinations may also exist. For instance, the two highest priority tasks can be fixed, Task 0 and Task 1 in the example in FIG. 18. The next priority slots are round-robin, so Tasks 3-7 rotate through the slots. The rest of the hardware tasks have time-based priority, so the priority slots 8-31 are allocated according to the time left to run the task.

In the SOC embodiment, communication is a bit more complex. The input and output message pending register architecture is identical to that of the logic only embodiment, except there are 32 bits in each register, one bit for each Hardware Task.

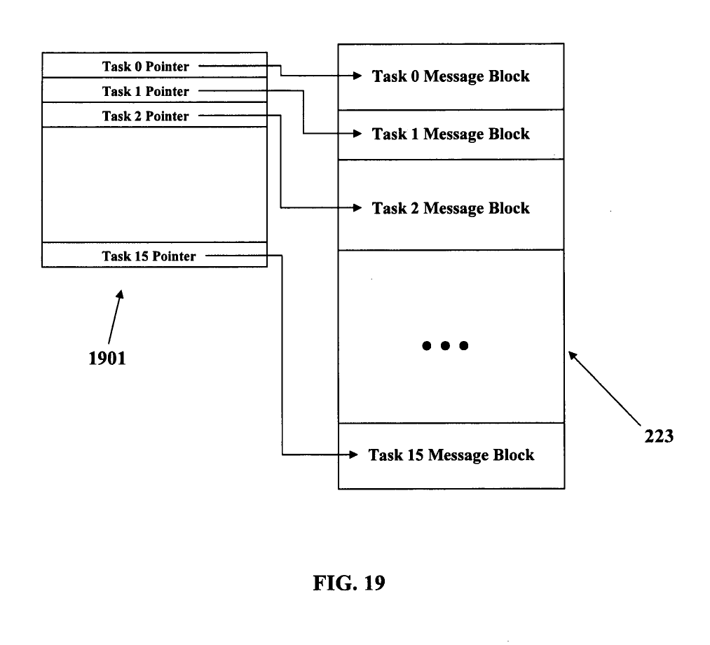

The messages are not confined to fixed-length blocks, however. Instead, as seen in FIG. 19, there are message pointers 1901 for each hardware task that point to the proper block in data memory 223. The blocks in memory can be contiguous or not, they can be in order or not, and they can have differing sizes.

In the architecture of the invention, there is essentially no difference in executing tasks that would normally be done in hardware and tasks that would normally be done in software. A processor might be executing 8 major tasks, while being surrounded by 8 peripherals. In the architecture of the invention, the 8 software tasks can be allocated to hardware tasks, and the 8 peripherals to another 8 hardware tasks. This eliminates the need to emulate a processor, switch contexts, or run complicated operating systems.

The architecture of the present invention executes up to 32 hardware tasks in parallel. Compiler 600 has features that make this more efficient. One is a compiler post-processor that analyzes the code and the priority structure and then allocates the instruction words to the various execution units so that there is a minimum of interference between the hardware tasks. For instance, two hardware tasks may use an ALU heavily. The post-processor would then allocate first hardware task to ALU1, and the second hardware task to ALU2. This minimizes impact they have on each other.

A user will be able to command compiler 600 to either pack the Instruction Word as tightly as possible for high-priority, high-bandwidth tasks, or let it be loose for low-priority, low-bandwidth tasks. This can be done on a hardware task by hardware task basis.

Compiler 600 will, under user control, attempt to place as many instructions in-line as possible, minimizing the number of jumps and branches required. This will minimize the use of the branch instruction execution unit and improve overall system throughput.

The invention has been described in terms of specific embodiments of the invention. It will be appreciated by those skilled in the art that various changes and modifications can be made to the embodiments described without departing from the spirit or scope of the present invention.

What is claimed is:

1. A customizable integrated circuit, comprising:
a processor on a single integrated circuit and operable to concurrently execute a plurality of tasks;
a plurality of executable programs for operating said processor in accordance with corresponding algorithms, said processor operable to execute said plurality of executable programs in parallel;
a plurality of locations for providing logical interconnects between said executable programs;
whereby said processor is programmable to provide customer specific logic functions and logical interconnects between said logic functions.

2. A customizable integrated circuit in accordance with claim 1, wherein:
said processor is responsive to very long instruction words (VLIW) to concurrently execute said plurality of executable programs.

3. A method for providing a customizable integrated circuit, comprising;
providing a chip having a meta-processor formed thereon;
structuring said meta-processor to concurrently execute a plurality of tasks;
providing a plurality of executable programs for operating said meta-processor in accordance with corresponding algorithms,
operating said meta-processor to execute said plurality of executable programs in parallel; and
programming a plurality of programmable locations for providing logical interconnect between said executable programs;
whereby said processor is programmable to provide customer specific logic functions and logical interconnects between said logic functions.

4. A method for providing customizable integrated circuits, comprising:
providing an integrated circuit comprising:
a plurality of execution units; a plurality of hardware task instruction memories, each of said hardware task instruction memories containing program code for a hardware task, said program code emulating a logic block; and a VLIW instruction register coupled to all of said plurality of execution units and coupled to each of said instruction memories;
emulating a plurality of hardware task functions to be performed by said integrated circuit to produce a corresponding plurality of instruction files;
storing each file of said plurality of instruction files in a corresponding one of said hardware task instruction memories;
forming VLIW instructions each comprising instruction words retrieved from one or more of said plurality of instruction files, each instruction word being used to control a corresponding execution unit;
utilizing each said VLIW instruction to cause one or more of said execution units to execute a function, each said VLIW instruction being usable to cause a plurality of said execution units to operate concurrently; and
providing pluralities of programmable locations to programmably establish communication interconnection paths.

5. A method in accordance with claim 4, comprising:
prioritizing execution of said instruction files.

6. A method in accordance with claim 5, comprising:
combining said instruction words for said plurality of instruction files based upon prioritization.

7. A method in accordance with claim 4, comprising:
providing a plurality of program counters, each program counter being associated with a corresponding instruction file.

8. A method in accordance with claim 4, comprising:
at least one of said execution units comprises at least one arithmetic logic unit.

9. A method in accordance with claim 8, comprising:
at least one of said execution units comprises a programmable input/output unit.

10. A method in accordance with claim 4, comprising:
providing a task compactor coupled to said plurality of hardware task memories and operable to combine instructions from said plurality of hardware task instruction memories.

11. A method in accordance with claim 10, comprising:
prioritizing said hardware task functions; and
utilizing said prioritization to determine the combining by said task compactor.

12. A method for providing customizable integrated circuits, comprising:
providing an integrated circuit comprising:
a plurality of execution units; a plurality of hardware task instruction memories, each of said hardware task instruction memories containing program code for a hardware task, said program code emulating a logic block; a cache controller; a plurality of cache memories each coupled to one of said plurality of execution units and each coupled to a corresponding one of said instruction task memories;
emulating a plurality of hardware task functions to be performed by said integrated circuit to produce a corresponding plurality of instruction files;
storing each file of said plurality of instruction files in a corresponding one of said hardware task instruction memories;
forming VLIW instructions each comprising instruction words retrieved from one or more of said plurality of cache memories, each instruction word being used to control a corresponding execution unit;
utilizing each said VLIW instruction to cause one or more of said execution units to execute a function, each said VLIW instruction being usable to cause a plurality of said execution units to operate concurrently; and
providing pluralities of programmable locations to programmably establish communication interconnection paths.

13. A customizable integrated circuit, comprising:
a plurality of execution units;
a plurality of hardware task instruction memories, each of said hardware task instruction memories containing program code emulating a logic block; and
a VLIW instruction register coupled to all of said plurality of execution units and coupled to each of said instruction memories;
a compactor forming VLIW instructions each comprising instruction words retrieved from one or more of said plurality of instruction files, each instruction word being used to control a corresponding execution unit to execute a function, each said VLIW instruction being usable to cause a plurality of said execution units to operate concurrently; and
a plurality of programmable locations to programmably establish communication interconnection paths.

14. A customizable integrated circuit in accordance with claim 13, comprising:
a data memory accessible by each execution unit of said plurality of execution units.

15. A customizable integrated circuit in accordance with claim 14, comprising:
a plurality of hardware task register files programmably selectively usable with corresponding execution units.

16. A customizable integrated circuit in accordance with claim 13, comprising:
a plurality of cache memories each associated with corresponding ones of said hardware task instruction memories and disposed between said corresponding one hardware task instruction memory and said instruction register.
